(19) United States
(12) Patent Application Publication
(10) Pub. No.: US 2004/0018451 A1
(43) Pub. Date: Jan. 29, 2004

(54) Photoresist developer-soluble organic bottom antireflective composition and photolithography and etching process using the same

(75) Inventor: Sang-Jun Choi, Seoul (KR)

Correspondence Address: F. Chau & Associates, LLP, Suite 501, 1900 Hempstead Turnpike, East Meadow, NY, 11554, US

(73) Assignee: Samsung Electronics Co., Ltd.

(21) Appl. No.: 10/400,029

(22) Filed: Mar. 26, 2003

(30) Foreign Application Priority Data
Jul. 23, 2002 (KR) 2002-43314

(51) Int. Cl. G03F 7/20; G03F 7/40; G03F 7/30; G03F 7/038

(52) U.S. Cl. 430/313; 430/950; 430/323; 430/316; 430/281.1; 430/286.1

(57) ABSTRACT

An organic bottom antireflective composition containing an aromatic polymer compound, a thermal cross-linking agent, and an organic solvent is provided. The aromatic polymer compound has a functional group that absorbs exposure light of a short wavelength of less than about 248 nm and is thermally cross-linkable and de-crosslinkable by acid hydrolysis. The thermal cross-linking agent causes a thermal cross-linking reaction by reacting with the functional group of the aromatic polymer compound. The organic bottom antireflective composition is soluble in a photoresist developer. When the organic bottom antireflective composition is-applied to a photolithography and etching process, a layer formed of the organic bottom antireflective composition can be developed together with a photoresist layer into a pattern in a development process following photoresist exposure and baking processes. As a result, the photolithography and etching process can be simplified, the initial thickness of deposition of the photoresist layer can be reduced, and a processing margin in etching increases.

This application claims the priority to Korean Patent Application No. 2002-43314, filed Jul. 23, 2002, which is incorporated herein by reference.

### BACKGROUND OF THE INVENTION

1. Field of the Invention

The present invention, generally, relates to an organic bottom antireflective composition and a photolithography and etching process. More particularly, the present invention relates to an organic bottom antireflective composition having new physical properties and a photolithography and etching process for the use of the composition.

2. Discussion of the Related Art

Antireflective coatings are used in general photolithography and etching processes to reduce the effect of light reflecting from the underlying layers into the patterned photoresist layers. Such antireflective coatings are classified into inorganic bottom antireflective coatings (BARCs) having optimized reflectivity and organic BARCs absorbing light through photoresist layers. Inorganic BARCs are conformable to underlying steps but are hard to remove and lead to pattern footing in a subsequent process. For these reasons, organic BARCs are more desirable than inorganic BARCs.

A general photolithography and etching process using an organic BARC is illustrated in the flowchart of FIG. 1. Initially, an organic BARC layer is formed on a target object to be etched, for example, a silicon substrate, an insulating layer, or a conductive layer, in step 10. After the organic BARC layer is baked at a high temperature in step 12, a photoresist layer is formed on the organic BARC layer and subjected to soft baking in step 14. After exposure and post-exposure baking in step 16, the photoresist layer is developed in step 18 to form a photoresist pattern. The organic BARC layer is etched using the photoresist pattern as an etching mask in step 20 (first etching), and subsequently the target object is etched in step 22 (second etching).

An important consideration in the photolithography and etching process is the thickness of the photoresist layer remaining after the first etching (step 20) for removing the organic BARC. As shown in FIG. 2, the photoresist pattern 50, immediately after the development of step 18, has a thickness of T1. However, in the first etching (step 20) for removing the organic BARC layer 40, the photoresist pattern 50 is also partially etched, so that the thickness T1 of the photoresist pattern 50 is reduced to T2, as shown in FIG. 3. In the second etching (step 22) for etching the target object 30, the photoresist pattern 50 is further etched and reduced in thickness to T3, as shown in FIG. 4. Since the underlying target object 30 is etched using the photoresist pattern 50 having the reduced thickness T2 after the first etching (step 20), in order to ensure a predetermined etch selectivity in etching the target object 30, it is desirable to minimize the reduction in the thickness of the photoresist pattern 50, e.g. a thickness T1 to a thickness T2, when the organic BARC layer 40 is removed in the first etching (step 20).

A problem in photolithography and etching processes using photoresists, such as ArF resists or F₂ resists, for exposure light with a wavelength of less than 248 nm is the loss of the photoresist pattern (e.g., the thickness reduction from T1 to T2) when the organic BARC layer 40 is removed in the first etching (step 20). As a result, the resulting photoresist pattern used as the etching mask for the target object 30 in the second etching (step 22) does not provide the etch selectivity needed in the manufacture of semiconductor devices.

Therefore, a need exists to reduce the loss of the photoresist pattern when etching to remove an organic BARC layer during the manufacture of semiconductor devices.

### SUMMARY OF THE INVENTION

The present invention provides an organic bottom antireflective composition (BARC) for use in photolithography and etching processes, which is soluble in a photoresist developer and thus needs no additional etching process for removing an organic bottom antireflective layer.

The invention provides a simplified, improved etch selectivity photolithography and etching process for the use of the photoresist developer-soluble BARC.

According to an embodiment of the present invention, the invention provides an organic BARC comprising an aromatic polymer compound, a thermal cross-linking agent, and an organic solvent. The aromatic polymer compound has a functional group that absorbs exposure light of a short wavelength of less than about 248 nm and is thermally cross-linkable and de-crosslinkable by acid hydrolysis. The thermal cross-linking agent causes a thermal cross-linking reaction by reacting with the functional group of the aromatic polymer compound. In addition, the organic BARC is soluble in a phoresist developer.

According to another embodiment of the present invention, the invention provides a photolithography and etching process comprising forming an organic BARC layer soluble in a developer for a photoresist on a target object to be etched, wherein the organic BARC layer contains an aromatic polymer compound having a functional group that absorbs exposure light of a short wavelength of less than about 248 nm and is thermally cross-linkable and de-crosslinkable by acid hydrolysis. The thermal cross-linking agent causes a thermal cross-linking reaction by reacting with the functional group of the aromatic polymer compound, and an organic solvent. Subsequently, the organic BARC layer is thermally cross-linked by baking, followed by formation of a photoresist layer on the cross-linked organic BARC layer. Next, the photoresist layer is exposed and baked so that hydrolysis by acid occurs in an exposed region of the photoresist layer, and de-crosslinking by acid occurs in the organic BARC layer underneath the exposed region of the photoresist layer. A photoresist pattern and an organic BARC layer pattern are simultaneously formed by dissolving the hydrolyzed exposed region of the photoresist layer and the de-crosslinked organic BARC layer underneath the exposed region in the developer. Lastly, the target object is etched using the photoresist pattern and the organic BARC layer pattern as an etching mask.

According to another embodiment of the present invention, it is preferable that the aromatic polymer compound be one of Novolak resin and polyhydroxystyrene resin. It is preferable that the thermal cross-linking agent be a vinyl ether derivative having the following formula:

R—(—OCH═CH₂)ₓ

where x is an integer from 2 to 4, R is a C₁-C₂₀ hydrocarbon or an oligomer having a weight average molecular weight of about 500 to about 5000. It is more preferable that the thermal cross-linking agent be one selected from the group consisting of 1,4-butandiol divinyl ether, tri(ethylene glycol)divinyl ether, trimethylolpropane trivinyl ether, and 1,4-cyclohexanedimethanol divinyl ether.

It is preferable that the amount of the thermal cross-linking agent be in the range of about 1% to about 30% by weight based on the weight of the aromatic polymer compound.

It is preferable that the photoresist used in the present invention be an ArF eximer laser photoresist or F₂ eximer laser photoresist containing a photoacid generator. It is preferable that the developer used in the present invention be a tetramethylammonium hydroxide solution.

It is preferable that the organic solvent be immiscible and unreactive with the photoresist.

### BRIEF DESCRIPTION OF THE DRAWINGS

The above features and advantages of the present invention will become more apparent by describing in detail exemplary embodiments thereof with reference to the attached drawings in which:

FIG. 1 is a flowchart of a conventional photolithography and etching process;

FIGS. 2 through 4 are sectional views of the resulting structures in steps 18, 19, and 20 of FIG. 1, respectively; and

FIG. 5A through FIG. 10 are sectional views illustrating each step of a photolithography and etching process using an organic bottom antireflective composition (BARC) according to the present invention, and particularly,

FIGS. 5B, 6B, and 8B show the chemical formula of the main component of the organic BARC at each step in a photolithography and etching process, according to another embodiment of the present invention.

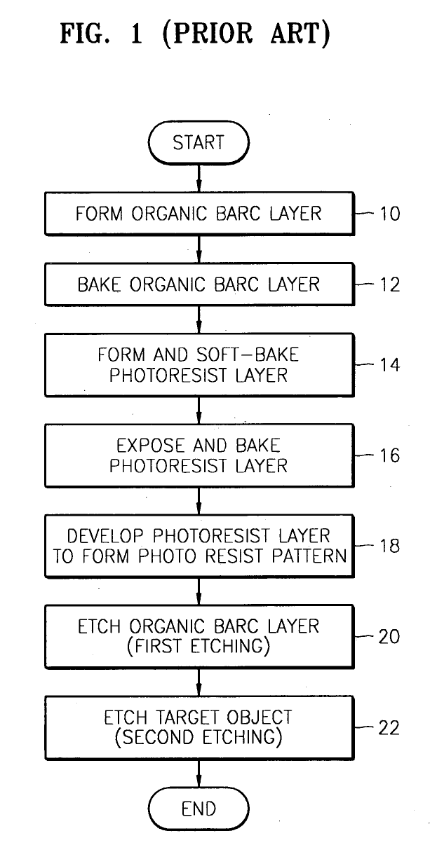

### DETAILED DESCRIPTION OF THE INVENTION

Hereinafter, an organic bottom antireflective composition (BARC) and a photolithography and etching process using the BARC according to the present invention will be described in detail. The invention may be embodied in many different forms and should not be constructed as being limited to the following embodiments, evaluation examples, and experimental examples; rather, the following embodiments, evaluation examples, and experimental examples are provided so that this disclosure will be thorough and complete, and will fully convey the concept of the invention to those skilled in the art. In the following chemical formulae, like characters are used to indicate like substituted groups.

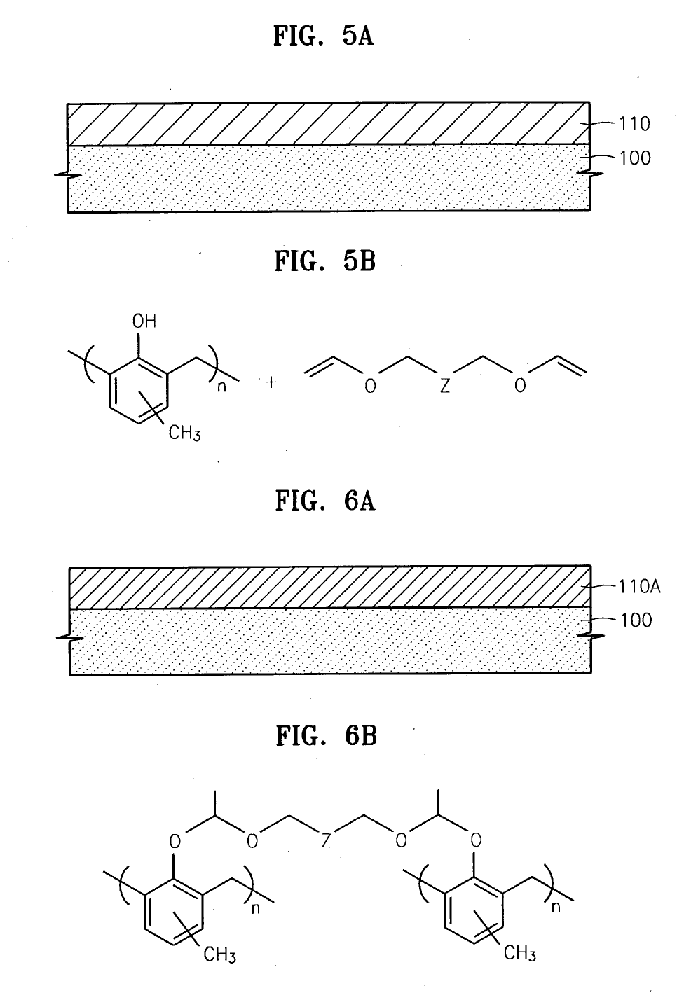

FIGS. 5A through 10 are sectional views for illustrating each step of a photolithography and etching process using an organic BARC, according to an embodiment of the present invention, and particularly, FIGS. 5B, 6B, and 8B show the chemical formula of the main component of the organic BARC at each step in the process. Referring to FIG. 5A, an organic BARC layer 110 is formed by coating a target object 100 to be etched with the organic BARC. The target object 100 to be etched can be a silicon substrate in which, for example, trenches will be formed. The target object 100 to be etched can be any material layer, such as an insulating layer or a conductive layer, used in the manufacture of semiconductors. In this embodiment, the silicon substrate in which trenches will be formed is exemplarily used as the target object 100 to be etched.

The organic BARC used in forming the organic BARC layer 110 includes an aromatic polymer compound having a functional group that absorbs short-wavelength exposure light of less than about 248 nm and is thermally cross-linkable and de-crosslinkable by acid, a thermal cross-linking agent causing a cross-linking reaction with the functional group of the aromatic polymer compound, and an organic solvent. The organic BARC is soluble in an alkaline photoresist developer.

The polymer compound in the organic BARC composition should be able to absorb exposure light of a short-wavelength, e.g., exposure light of a wavelength less than about 248 nm. Therefore, aromatic polymer compounds are preferable for the polymer compound. For example, Novolak resin as an I-line (365 nm) resist, or polyhydroxy styrene as a KrF (248 nm) eximer laser resist, which are widely known for their convenience in use and cost effectiveness, are suitable for the polymer compound.

The aromatic polymer compound includes in its structure a functional group that may be cross-linked by the thermal cross-linking agent when baked at high temperature and is de-crosslinked by the catalytic function of an acid.

In addition, the thermal cross-linking agent includes a functional group that effects the cross-linking reaction with the aromatic polymer compound and is de-crosslinked by acid hydrolysis. Further, suitable thermal cross-linking agents that do not affect the performance of the organic BARC layer are selected in consideration of various factors, e.g. storage stability.

An example of the thermal cross-linking agent for the organic BARC includes a vinyl ether derivative having a multi-functional group, as expressed by formula (1) below:

R—(—OCH═CH₂)ₓ (1)

where x is an integer from 2 to 4, R is a C₁-C₂₀ hydrocarbon or an oligomer having a weight average molecular weight of about 500 to about 5000.

Examples of the vinyl ether derivative having formula (1) above include 1,4-butandiol divinyl ether, tri(ethylene glycol) divinyl ether, trimethylolpropane trivinyl ether, and 1,4-cyclohexanedimethanol divinyl ether.

When the thermal cross-linking agent having formula (1) above is mixed together with the aromatic polymer compound in the organic solvent to prepare the organic BARC, the thermal cross-linking agent is used in an amount of about 1% to about 30% by weight based on the weight of the aromatic polymer compound.

The organic solvent for the organic BARC should be immiscible and unreactive with a photoresist layer to be formed on the organic BARC layer. If the organic solvent is miscible and reacts with the photoresist layer formed on the organic BARC layer, the properties of the photoresist layer can degrade. Accordingly, the organic solvent for the organic BARC may be varied according to the kind of the photoresist layer to be formed. A suitable example of the organic solvent includes isopropyl alcohol.

FIG. 5B illustrates the chemical structure of the organic BARC layer 110 formed of an organic BARC composition containing Novolak resin as the aromatic polymer compound and a vinyl ether derivative as the thermal cross-linking agent. In the chemical formula of FIG. 5B, Z is a C₃-C₂₀ hydrocarbon.

FIG. 6A illustrates the formation of a thermally cross-linked organic BARC layer 110A by baking the organic BARC layer 110 according to predetermined parameters, e.g. time and temperature. The organic BARC layer 110 is coated on the target object 100, wherein the organic BARC layer 110 comprises the mixture of the aromatic polymer compound and the thermal cross-linking agent without reacting, as shown in the formula of FIG. 5B. However, after the organic BARC layer 110 is baked at a temperature of about 150-200° C., the aromatic polymer compound is cross-linked by the thermal cross-linking agent, as shown in the formula of FIG. 6B.

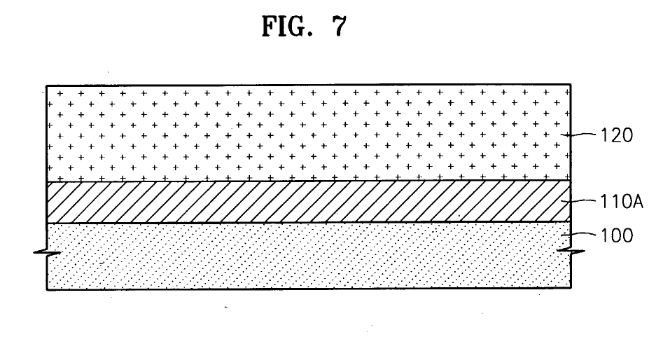

Next, a photoresist layer 120 is formed on the thermally cross-linked organic BARC layer 110A, as shown in FIG. 7. The photoresist layer 120 is formed by coating an ArF eximer laser (193 nm) or F₂ laser photoresist containing a photoacid generator (PAG), removing the solvent from the coated photoresist, and soft baking the photoresist so as to enhance the binding strength of the resulting cross-linked organic BARC layer 110A. Soft baking is performed at a temperature in the range of about 90-150° C. for about 60-120 seconds.

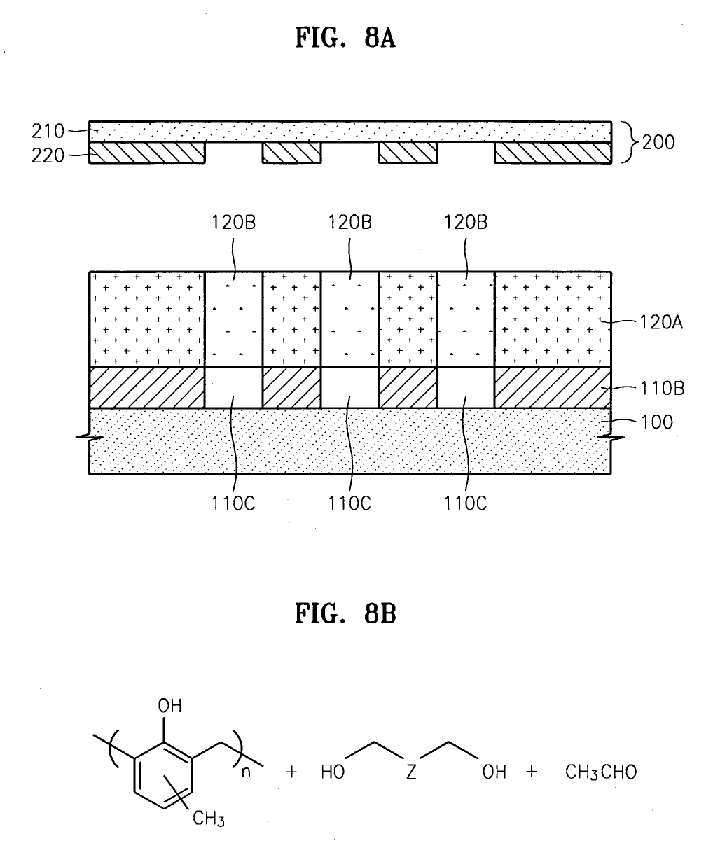

Referring to FIG. 8A, the photoresist layer 120 is exposed to light having a wavelength of less than 248 nm using a mask 200 having a predetermined pattern and then baked, which is called “post-exposure baking (PEB).” PEB is performed at a temperature of about 90-150° C. for about 60-120 seconds.

In an exposed region 120B of the photoresist layer 120 acids (H⁺) are generated from the PAG and diffusion and acid hydrolysis of the acids are activated by PEB. As a result, the exposed region 120B becomes soluble in a developer. Some acids in the exposure region 120B diffuse into the underlying organic BARC layer 110C to de-crosslink the cross-linked organic BARC layer 110C.

In other words, in the organic BARC layer 110C underneath the exposed region 120B, de-crosslinking occurs by acid hydrolysis to generate a large amount of substances soluble in the photoresist developer, as illustrated in FIG. 8B.

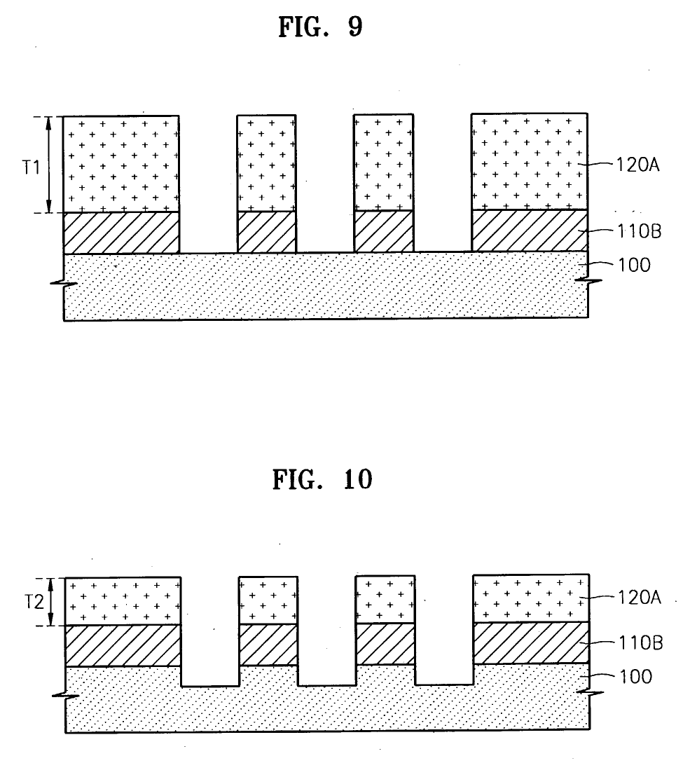

Next, referring to FIG. 9, the exposed region 120B and a portion of the organic BARC layer 110C underneath the exposed region 120B simultaneously dissolve during development to form a photoresist pattern 120A and an organic BARC pattern 110B.

Development is performed using a photoresist developer, for example, about 2.38% tetramethylammonium hydroxide (TMAH) by weight, which is a kind of alkaline developer.

Since in the organic BARC layer 110C underneath the exposed region 120B de-crosslinking has occurred by acid hydrolysis during exposure and PEB, the organic BARC layer 110C as well as the exposed region 120B dissolve in the developer solution. Accordingly, a separate etching process for removing the underlying organic BARC layer 110C, which is performed in the prior art, is not required. As a result, loss of the photoresist pattern 120A, which occurs when the organic BARC layer 110 is removed by additional etching as in the prior art, can be prevented, and the initial thickness T1 of the photoresist pattern 120A remains. Therefore, a processing margin in forming the photoresist pattern 120A increases.

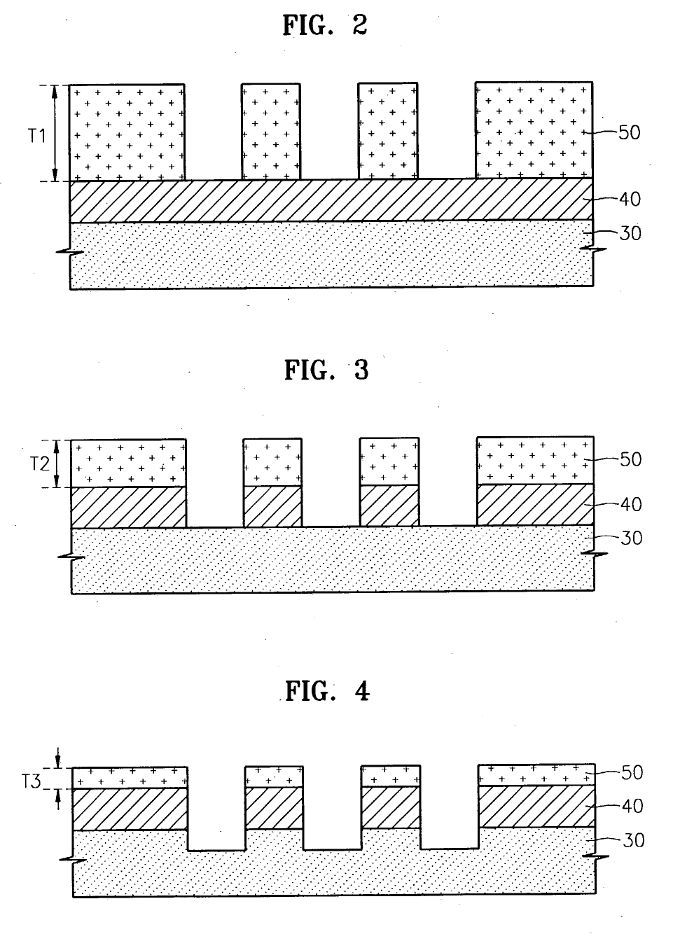

Next, as shown in FIG. 10, the target object 100 is etched using the photoresist pattern 120A and the organic BARC pattern 110B, which are simultaneously formed, as an etching mask. At this time, the thickness of the photoresist pattern 120A reduces from T1 to T2, but the thickness reduction is smaller than in conventional photolithography and etching processes as illustrated in FIGS. 2 through 4 since in the present invention etching is performed only once. Accordingly, a higher etching selectivity can be ensured in etching the target object 100. The organic BARC pattern 110B containing the aromatic polymer compound as a major component is highly resistant to dry etching. Since the photoresist pattern 120A and the organic BARC pattern 110B, which is resistant against dry etching, are used together as the etching mask for the target object 100, the target object 100 can be etched with a higher etching selectivity. The thickness of deposition of the photoresist layer can be reduced compared to the prior art, and the aspect ratio of the photoresist layer during etching can also be reduced. Also, the manufacturing cost is saved.

The present invention will be described in greater detail with reference to the following examples. The technical descriptions that can be inferred by those of ordinary skill in the art are not fully described here. For reference, most reagents used in the following examples, except for particular reagents, as commercially available from Aldrich Chemical Co.

### EXAMPLE 1

The effect of the amount of a vinyl ether derivative added as the thermal cross-linking agent into the organic BARC according to the present invention was evaluated using the following method.

One gram of Novolak resin having a weight average molecular weight of 35000 was used as the aromatic polymer compound. 0%, 5%, 10%, 20% and 30% by weight (wt %) trimethylolpropane trivinyl ether, based on the weight of the polymer compound, were added as the thermal cross-linking agent into an organic solvent containing about 1% to about 5% solids to prepare different organic BARCs.

The prepared organic BARCs were spin coated on five bare wafers, respectively, at about 2500-4000 rpm and baked at about 180° C. for about 90 seconds to induce a thermal cross-linking reaction.

Subsequently, an ArF resist (EPIC-V4, Shipley Co.) was coated on the cross-linked organic BARC layer to a thickness (Tpr) of about 3000Å and subjected to soft baking at about 120° C. for about 90 seconds. Next, the entire photoresist layer was exposed to an ArF eximer laser (having a NA of 0.6, ISI) and then baked (PEB) at about 110° C. for about 60 seconds.

After development using about 2.38 wt % TMAH solution for about 90 seconds, the ratio of the organic BARC layer remaining on the wafer to the initial organic BARC layer was measured. The results are shown in Table 1.

TABLE 1

| | | | | | |
|---|---|---|---|---|---|
| The amount of thermal | 0 | 5 | 10 | 20 | 30 |
| cross-linking agent (wt %) | | | | | |
| Residual ratio (%) | 0 | 15 | 30 | 50 | 65 |

From the results of Table 1 above, the thermal cross-linking agent in an amount of about 30wt % or less is preferable in terms of residual ratio and manufacturing cost.

The following experimental examples are for the use of organic BARCs in a photolithography and etching process, according to another embodiment of the present invention.

### EXAMPLE 2

One gram of a commercially available Novolak resin, 0.3 g trimethylolpropane trivinyl ether as the thermal cross-linking agent, and a trace flourosurfactant were dissolved in isopropyl alcohol to prepare an organic BARC.

The prepared organic BARC was spin coated on a wafer having a silicon oxide layer at about 2500-4000 rpm, baked at about 150-200° C. for about 90 seconds to induce a thermal cross-linking reaction.

Subsequently, an ArF resist (EPIC-V4, Shipley Co.) was coated on the cross-linked organic BARC layer to a thickness (Tpr) of 3000Å and subjected to soft baking about 120° C. for about 90 seconds. Next, the photoresist layer was exposed to an ArF eximer laser (having a NA of 0.6, ISI) using a mask for defining a contact hole 0.16×0.16 μm and then baked (PEB) at about 110° C. for about 60 seconds.

After development using about 2.38wt % TMAH solution for about 90 seconds, a cross-section of the wafer was observed using a scanning electron microscope. As a result, it was found that a photoresist pattern and an organic BARC pattern can be formed simultaneously only through development.

Next, the silicon oxide layer was etched using plasma with both the photoresist and organic BARC patterns serving as an etching mask to form a contact hole. As a result, a contact hole pattern having a desired profile could be easily formed over the wafer.

### EXAMPLE 3

An organic BARC was prepared and a photolithography and etching process was performed in the same manner as in experimental example 1, except that 0.2 g 1,4-butandiol divinyl ether was used as the thermal cross-linking agent in the preparation of the organic BARC. As a result, a contact hole pattern having a desired profile could be easily formed over the wafer.

### EXAMPLE 4

An organic BARC was prepared and a photolithography and etching process was performed in the same manner as in experimental example 1, except that 0.1 g tri(ethylene glycol)divinyl ether was used as the thermal cross-linking agent in the preparation of the organic BARC. As a result, a contact hole pattern having a desired profile could be easily formed over the wafer.

### EXAMPLE 5

An organic BARC was prepared and a photolithography and etching process was performed in the same manner as in experimental example 1, except that 0.2 g 1,4-cyclohexanedimethanol divinyl ether was used as the thermal cross-linking agent in the preparation of the organic BARC. As a result, a contact hole pattern having a desired profile could be easily formed over the wafer.

### EXAMPLE 6

An organic BARC was prepared and photolithography and etching processes were performed in the same manner as in experimental example 1, except that 1.0 g a commercially available polyhydroxy styrene resin was used as the aromatic polymer compound. As a result, a contact hole pattern having a desired profile could be easily formed over the wafer.

As described above, the organic BARC according to the present invention is de-crosslinkable by acid hydrolysis and can be developed using a photoresist developer. These properties of the organic BARC according to the present invention are distinguished from those of the conventional organic BARC that needs an additional etching process.

Therefore, photolithography and etching processes can be simplified when using the organic BARC according to the present invention. In addition, in a subsequent dry etching process of a target object, a higher etching selectivity between a photoresist pattern and the target object is ensured, thereby increasing a processing margin in the etching process. Therefore, semiconductor devices can be manufactured at lower costs.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic bottom antireflective composition soluble in a developer for a photoresist, the composition comprising:
an aromatic polymer compound having a functional group that absorbs exposure light of a short wavelength of less than about 248 nm and is thermally cross-linkable and de-crosslinkable by acid;
a thermal cross-linking agent which causes a thermal cross-linking reaction by reaction with the functional group of the aromatic polymer compound; and
an organic solvent.

2. The organic bottom antireflective composition of claim 1, wherein the aromatic polymer compound is one of Novolak resin and polyhydroxy styrene resin.

3. The organic bottom antireflective composition of claim 1, wherein the thermal cross-linking agent is a vinyl ether derivative having the following formula:
R—(—OCH═CH₂)ₓ
where x is an integer from 2 to 4, R is a C₁-C₂₀ hydrocarbon or an oligomer having a weight average molecular weight of about 500 to about 5000.

4. The organic bottom antireflective composition of claim 4, wherein the thermal cross-linking agent is one selected from the group consisting of 1,4-butandiol divinyl ether, tri(ethylene glycol)divinyl ether, trimethylolpropane trivinyl ether, and 1,4-cyclohexanedimethanol divinyl ether.

5. The organic bottom antireflective composition of claim 1, wherein the amount of the thermal cross-linking agent is in the range of about 1% to about 30% by weight based on the weight of the aromatic polymer compound.

6. The organic bottom antireflective composition of claim 1, wherein the photoresist is an ArF eximer laser photoresist or F₂ eximer laser photoresist containing a photoacid generator.

7. The organic bottom antireflective composition of claim 1, wherein the organic solvent is immiscible and unreactive with the photoresist.

8. The organic bottom antireflective composition of claim 6, wherein the organic solvent is immiscible and unreactive with the photoresist.

9. The organic bottom antireflective composition of claim 1, wherein the developer is a tetramethylammonium hydroxide solution.

10. A photolithography and etching process comprising:
forming on a target object to be etched an organic bottom antireflective layer soluble in a developer for a photoresist, the organic bottom antireflective layer containing an aromatic polymer compound having a functional group that absorbs exposure light of a short wavelength of less than about 248 nm and is thermally cross-linkable and de-crosslinkable by acid hydrolysis, a thermal cross-linking agent which causes a thermal cross-linking reaction by reaction with the functional group of the aromatic polymer compound, and an organic solvent;
thermally cross-linking the organic bottom antireflective layer by baking;
forming a photoresist layer on the cross-linked organic bottom antireflective layer;
exposing and then baking the photoresist layer so that hydrolysis by acid occurs in an exposed region of the photoresist layer, and de-crosslinking by acid occurs in the organic bottom antireflective layer underneath the exposed region of the photoresist layer;
simultaneously forming a photoresist pattern and an organic bottom antireflective layer pattern by dissolving the hydrolyzed exposed region of the photoresist layer and the de-crosslinked organic bottom antireflective layer underneath the exposed region in the developer; and
etching the target object using the photoresist pattern and the organic bottom antireflective layer pattern as an etching mask.

11. The photolithography and etching process of claim 10, wherein the aromatic polymer compound is one of Novolak resin and polyhydroxystyrene resin.

12. The photolithography and etching process of claim 10, wherein the thermal cross-linking agent is a vinyl ether derivative having the following formula:
R—(—OCH═CH₂)ₓ
where x is an integer from 2 to 4, R is a C₁-C₂₀ hydrocarbon or an oligomer having a weight average molecular weight of about 500 to about 5000.

13. The photolithography and etching process of claim 12, wherein the thermal cross-linking agent is one selected from the group consisting of 1,4-butandiol divinyl ether, tri(ethylene glycol)divinyl ether, trimethylolpropane trivinyl ether, and 1,4-cyclohexanedimethanol divinyl ether.

14. The photolithography and etching process of claim 10, wherein the amount of the thermal cross-linking agent is in the range of about 1% to about 30% by weight based on the weight of the aromatic polymer compound.

15. The photolithography and etching process of claim 10, wherein in forming the photoresist layer comprises an ArF eximer laser photoresist containing a photoacid generator.

16. The photolithography and etching process of claim 10, wherein in forming the photoresist layer comprises a F₂ eximer laser photoresist containing a photoacid generator.

17. The photolithography and etching process of claim 10, wherein the organic solvent is immiscible and unreactive with the photoresist.

18. The photolithography and etching process of claim 15, wherein the organic solvent is immiscible and unreactive with the photoresist.

19. The photolithography and etching process of claim 10, wherein the developer is a tetramethylammonium hydroxide solution.
